(19) United States
(12) Patent Application Publication
(10) Pub. No.: US 2007/0051956 A1
(43) Pub. Date: Mar. 8, 2007

(54) THIN FILM TRANSISTOR

(76) Inventors: Chih-Jen Shih, Changhua County (TW); Chun-Hsiang Fang, Yilan County (TW); Te-Hua Teng, Taoyuan County (TW); Chia-Chien Lu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,159

(22) Filed: Aug. 31, 2005

(51) Int. Cl. H01L 29/00

(52) U.S. Cl. 257/69

(57) ABSTRACT

A thin film transistor having a substrate, a gate insulating layer, a double-gate structure, a first lightly doped region, and a second lightly doped region. The substrate has a source region and a drain region disposed on its opposite sides, a heavily doped region between source region and drain region, a first channel region between heavily doped region and source region and a second channel region between heavily doped region and drain region. The gate insulating layer covers the substrate. The double-gate structure has a first gate and a second gate disposed on gate insulating layer above the first and the second channel region, respectively. The first lightly doped region is disposed between second channel region and heavily doped region and the second lightly doped region between second channel region and drain region. The length of second lightly doped region is greater than that of first lightly doped region.

### BACKGROUND OF THE INVENTION

1. Field of Invention

The present invention relates to a thin film transistor. More particularly, the present invention relates to a thin film transistor capable of effectively suppressing the kink effect.

2. Description of Related Art

Because of its advantages such as a small volume, a light weight, the full-color display and so on, the active matrix display has been widely applied in products including mobile phones, digital cameras, computer displays and televisions, etc. And the quality of displaying images for the active matrix display relies greatly on its core component, i.e. the thin film transistor (TFT).

FIG. 1 schematically shows a top view of a thin film transistor in the prior art, and FIG. 2 schematically shows the relation curve between the drain voltage and the drain current for the thin film transistor. Please refer to FIGS. 1 and 2 at the same time. As the drain voltage (VD) of the drain 104 varies constantly, the drain current (IDS) varies as well. In general, the ideal operating current for the thin film transistor (TFT) 100 is the drain current (IDS) in the saturation region. However, for the TFT 100 a phenomenon called kink current tends to occur when the drain voltage VD reaches the kink voltage Vk. Accordingly, the way how to increase the kink voltage Vk of the TFT 100 to avoid the kink current has become one of the important subjects in the research nowadays.

FIG. 3 schematically shows a top view of a symmetric TFT in the prior art. Referring to FIG. 3, for the symmetric double-gate TFT 200, the first gate 222 and the second gate 224 have the same width, and there are lightly doped regions 205 on the two sides of the first gate 222 and second gate 224. Because the symmetric double-gate structure 220 enables the impedance between the source 202 and drain 204 to be increased, the kink effect can be suppressed for preventing the leakage current accordingly.

Nevertheless, only the current in the channel region (not shown) adjacent to the drain 204 reaches the saturation state when the voltage applied on the drain 204 is over the threshold voltage V_{T} (in FIG. 2) in this symmetric double-gate structure 220. And no matter what voltage is applied on the drain 204, the current in the channel region (not shown) adjacent to the source 202 appears linear relationship with this voltage. Therefore, when the drain voltage rises, the kink effect occurs in the channel region adjacent to the source 202 and causes the kink current.

To solve the drawbacks of the symmetric double-gate TFT 200, one asymmetric double-gate TFT is proposed. FIG. 4 schematically shows a top view of an asymmetric double-gate TFT in the prior art. Referring to FIG. 4, it's seen that the width 11 of the first gate 322 adjacent to the source 302 is larger than the width 12 of the second gate 324 adjacent to the drain 304.

As described above, the kink voltage for the asymmetric double-gate TFT 300 can be raised by providing the first gate 322 with a larger width 11. Further, under the limitation that the sum of widths 11 and 12 for the first and second gates 322, 324 is a constant, the width 12 of the second gate 324 needs to be shortened as possible so that the first gate 322 provided has a width 11 long enough. Nevertheless, provided that the width 12 of the second gate 324 is too small, the short channel effect and hot carrier effect tend to arise, thereby causing the leakage current of the asymmetric double-gate thin film transistor 300 and worsening the characteristics of the devices.

### SUMMARY OF THE INVENTION

In view of this, one object of the present invention is to provide a thin film transistor capable of suppressing the kink current effect.

Another object of the present invention is to provide a thin film transistor with high carrier mobility.

To achieve the above-mentioned objects or others, the present invention provides a thin film transistor. The thin film transistor comprises a substrate, a gate insulating layer, a double-gate structure, a first lightly doped region and a second lightly doped region. Wherein, the substrate comprises a source region, a drain region, a heavily doped region, a first channel region and a second channel region. The source region and the drain region are respectively disposed the opposite sides of the substrate. The heavily doped region is disposed between the source region and the drain region, the first channel region is disposed between the heavily doped region and the source region, and the second channel region is disposed between the heavily doped region and the drain region. Besides, the gate insulating layer covers the substrate, and the double-gate structure comprises a first gate disposed on the gate insulating layer above the first channel region and a second gate disposed on the gate insulating layer above the second channel region. In addition, the first lightly doped region is disposed between the second channel region and the heavily doped region and the second lightly doped region is disposed between the second channel region and the drain region. Also, the length of the second lightly doped region is larger than the length of the first lightly doped region.

In one preferred embodiment of the present invention, when the substrate is a p-type silicon substrate, the heavily doped region, the first lightly doped region and the second lightly doped region are n-type doped regions. Inversely, when the substrate is an n-type silicon substrate, the heavily doped region, the first lightly doped region and the second lightly doped region are p-type doped regions. Additionally, the width of the second gate is smaller than the width of the first gate. Moreover, a material of the gate insulating layer includes silicon oxide, for example.

The present invention also provides a thin film transistor. The thin film transistor comprises a substrate, a gate insulating layer and a double-gate structure. Here, the substrate comprises a source region, a drain region, a first lightly doped region, a second lightly doped region, a first channel region and a second channel region. The source region and the drain region are respectively disposed on the opposite sides of the substrate. The first lightly doped region is disposed on the substrate and between the source region and the drain region. The first channel region is disposed between the first lightly doped region and the source region, the second channel region is disposed between the first lightly doped region and the drain region, and the second lightly doped region is disposed between the second channel region and the drain region. Besides, the gate insulating layer covers the substrate, and the double-gate structure comprises a first gate disposed on the gate insulating layer above the first channel region and a second gate disposed on the gate insulating layer above the second channel region. Additionally, the width of the second gate is smaller than the width of the first gate.

In one preferred embodiment of the present invention, the above-mentioned thin film transistor further comprises a dielectric layer and a metal layer. Wherein, the dielectric layer having an opening may be disposed on the gate insulating layer and it covers the double-gate structure. Further, the metal layer is disposed on the dielectric layer and above the double-gate structure and the first lightly doped region. And the metal layer is filled in the opening to be electrically connected with the double-gate structure. In addition, when the substrate is a p-type silicon substrate, the first lightly doped region and the second lightly doped region are n-type doped regions. Inversely, when the substrate is an n-type silicon substrate, the first lightly doped region and the second lightly doped region are p-type doped regions.

In one preferred embodiment of the present invention, the above-mentioned thin film transistor may further comprises a third lightly doped region disposed between the first channel region and the source region and the length of the third lightly doped region is smaller than the length of the first lightly doped region. In addition, when the substrate is a p-type silicon substrate, the first lightly doped region, the second lightly doped region and the third lightly doped region are n-type doped regions. Inversely, when the substrate is an n-type silicon substrate, the first lightly doped region, the second lightly doped region and the third lightly doped region are p-type doped regions.

In one preferred embodiment of the present invention, a material of the gate insulating layer is silicon oxide, for example.

In the thin film transistor based on the present invention, the length of the second lightly doped region is larger than the length of the first lightly doped region by increasing the length of the second lightly doped region so as to form an asymmetric lightly doped region structure. The asymmetric the lightly doped structure can increase the impedance between the source and the drain and thus improve the leakage current of the thin film transistor.

Besides, a lightly doped region is directly formed between the first gate and the second gate in the asymmetric double-gate structure owning a width of the first gate larger than that of the second gate, and thus the impedance between the first region and the second region can be raised to improve the leakage current effect of the thin film transistor.

Moreover, the metal layer disposed on the double-gate structure is electrically connected with the double-gate structure and covers the lightly doped region. By doing so, with usage of the metal layer, the photo-leakage current for the thin film transistor due to lighting can be avoided and the carrier mobility of the TFT can be improved as well.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically shows a top view of one thin film transistor in the prior art.

FIG. 2 schematically shows the relationship curve between the drain voltage and drain current of the thin film transistor.

FIG. 3 schematically shows a top view of one symmetric thin film transistor in the prior art.

FIG. 4 schematically shows a top view of one asymmetric thin film transistor in the prior art.

FIG. 5 schematically shows a cross-section view of a thin film transistor according to the first embodiment of the present invention.

FIG. 6A schematically shows a top view of a thin film transistor according to the second embodiment of the present invention.

FIG. 6B schematically shows the cross-section diagram I-I′ in FIG. 6C.

FIG. 6C schematically shows a top view of a thin film transistor with a metal layer according to the second embodiment of the present invention.

FIG. 6D schematically shows the cross-section diagram II-II′ in FIG. 6C.

FIG. 6E schematically shows the cross-section diagram III-III′ in FIG. 6C.

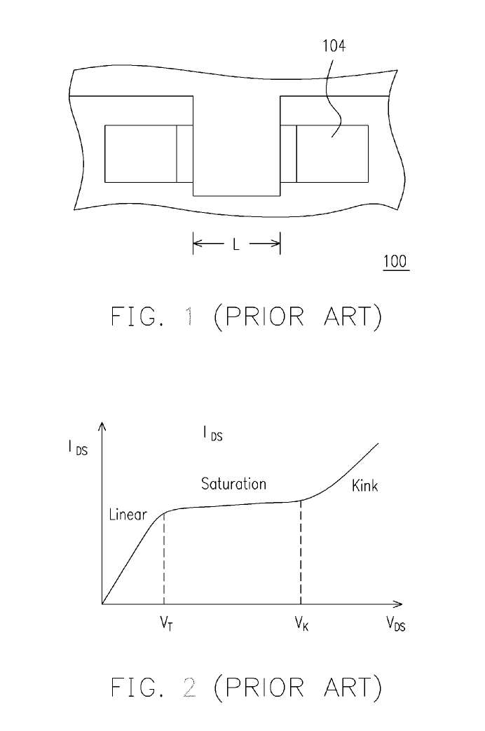

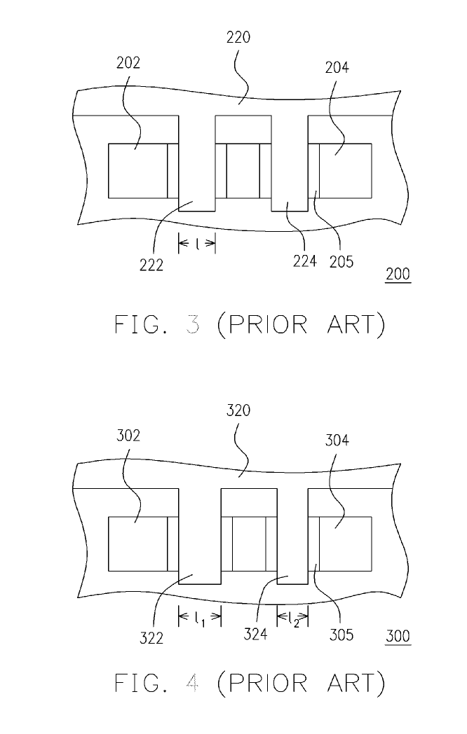

### DESCRIPTION OF THE PREFERRED EMBODIMENTS

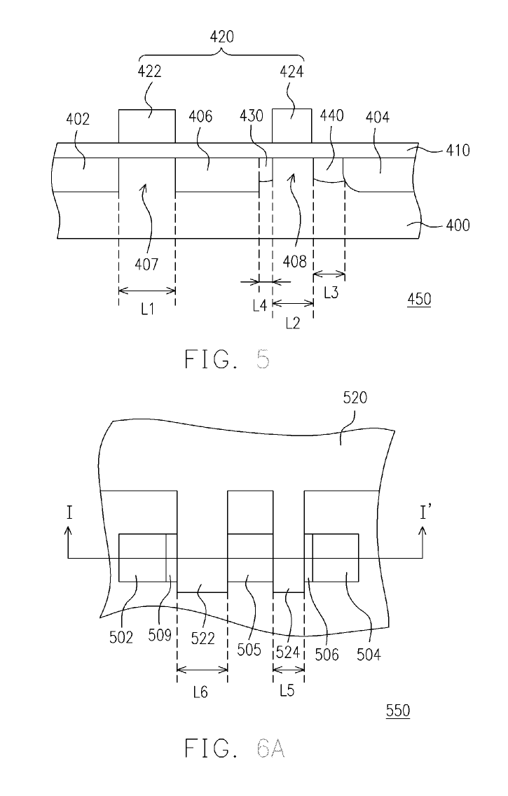

FIG. 5 schematically shows a cross-section view of a thin film transistor according to a first embodiment of the present invention. Referring to FIG. 5, the thin film transistor 450 comprises a substrate 400, a gate insulating layer 410, a double-gate structure 420, a first lightly doped region 430 and a second lightly doped region 440. Also, the substrate 400 comprises a source region 402, a drain region 404, a heavily doped region 406, a first channel region 407 and a second channel region 408. The source region 402 and drain region 404 are disposed respectively on the opposite sides of the substrate 400. The heavily doped region 406 is disposed between the source region 402 and drain region 404, the first channel region 407 is disposed between the heavily doped region 406 and source region 402, and the second channel region 408 is disposed between the heavily doped region 406 and drain region 404. In addition, the first lightly doped region 430 is disposed between the second channel region 408 and heavily doped region 406, and the second lightly doped region 440 is disposed between the second channel region 408 and drain region 404. It's worthy to note that the length L3 of the second lightly doped region 440 is larger than the length L4 of the first lightly doped region 430.

As discussed previously, the gate insulating layer 410 covers the substrate 400 and the material of the gate insulating layer 410 is silicon oxide for example. The double-gate structure 420 comprises a first gate 422 disposed on the gate insulating layer 410 above the first channel region 407 and a second gate 424 disposed on the gate insulating layer 410 above the second channel region 408. It's worthy to note here the sum of widths L1 and L2 of the first gate 422 and second gate 424 is a constant, and the width L2 of the second gate 424, for example, is smaller than the width L1 of the first gate 422 in the present embodiment. That is, the length of the channel region 407 is larger than that of the channel region 408.

Besides, the substrate 400 in the present embodiment is p-type silicon substrate. The heavily doped region 406, the first lightly doped region 430 and the second lightly doped region 440 are all n-type doped regions, for example. In one preferred embodiment, for example, the substrate 400 is n-type silicon substrate and the heavily doped region 406, the first lightly doped region 430 and the second lightly doped region 440 are all p-type doped regions.

Since the length of the second lightly doped region 440 disposed between the drain region 404 and the heavily doped region 406 in the thin film transistor 450 is comparatively larger, compared to the length of lightly doped region in the prior art, the short channel effect occurring in the channel region 408 with a shorter length can be avoided and the characteristics of devices for the thin film transistor 450 can be improved.

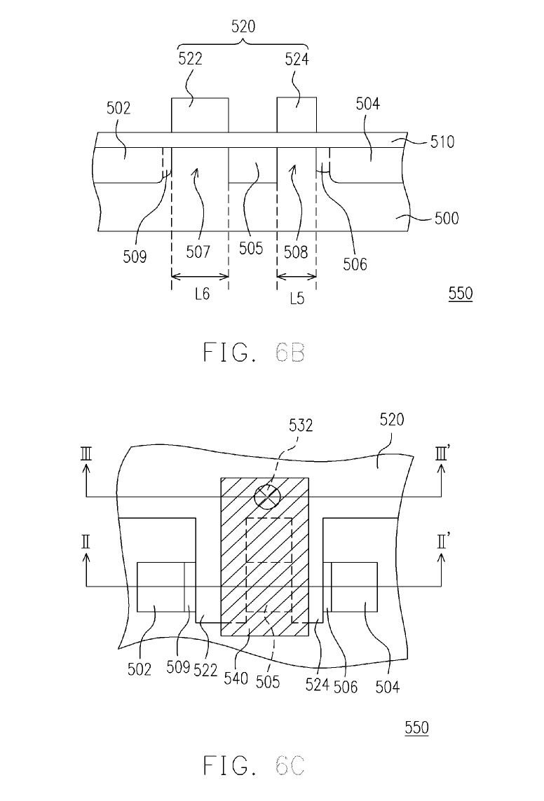

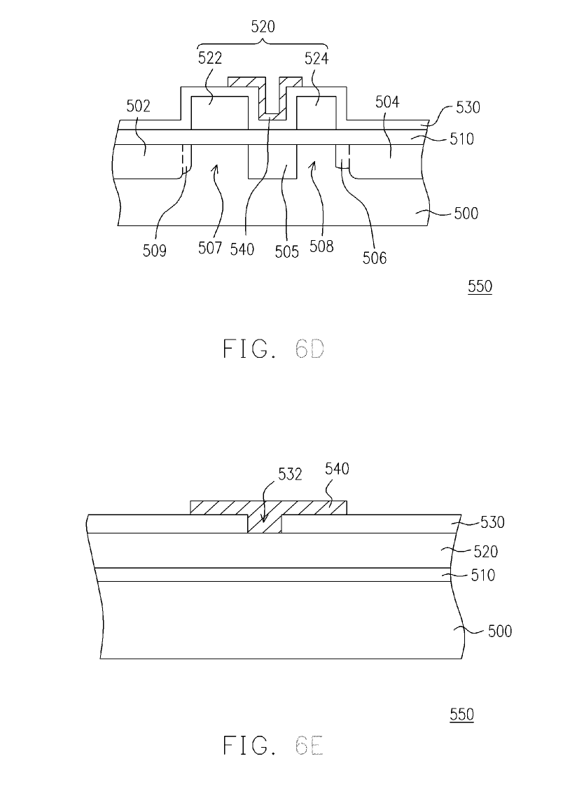

FIG. 6A schematically shows a top view of a thin film transistor according to a second embodiment of the present invention, and FIG. 6B schematically illustrates the cross-section diagram I-I′ in FIG. 6A. Please refer to FIGS. 6A and 6B simultaneously. The thin film transistor 550 comprises a substrate 500, a gate insulating layer 510 and a double-gate structure 520. Moreover, the substrate 500 comprises a source region 502, a drain region 504, a first lightly doped region 505, a second lightly doped region 506, a first channel region 507 and a second channel region 508. The source region 502 and drain region 504 are disposed respectively on the opposite sides of the substrate 500. The first lightly doped region 505 is disposed on the substrate 500 and between the source region 502 and drain region 504. The first channel region 507 is disposed between the first lightly doped region 505 and source region 502, the second channel region 508 is disposed between the first lightly doped region 505 and drain region 504, and the second lightly doped region 506 is disposed between the second channel region 508 and drain region 504.

As discussed previously, the gate insulating layer 510 covers the substrate 500 and the material of the gate insulating layer 510 is silicon oxide for example. The double-gate structure 520 is disposed on the gate insulating layer 510. The double-gate structure 520 comprises a first gate 522 disposed on the gate insulating layer 510 above the first channel region 507 and a second gate 524 disposed on the gate insulating layer 510 above the second channel region 508. Here, the sum of widths L5 and L6 of the first gate 522 and second gate 524 is a constant, and the width L5 of the second gate 524, is smaller than the width L6 of the first gate 522. That is, the length of the channel region 507 is larger than that of the channel region 508.

In particular, the first lightly doped region 505 formed between the first gate 522 and second gate 524 in the asymmetric double-gate structure 520 enables the impedance between gates 522 and 524 to be increased. Thus, the kink voltage can be raised and formation of the kink effect can be delayed, providing more strong suppression of leakage current in the thin film transistor 550. Additionally, because there is no need to deal with the alignment precision required for forming a heavily doped region between the first gate 522 and second gate 524, the distance between the first gate 522 and second gate 524 could be reduced as possible and volumes of devices can be minimized.

Still refer to FIG. 6B. To enhance the effect of suppressing the leakage current of the thin film transistor 550, a third lightly doped region 509 disposed between the first channel region 507 and source region 502 is further comprised. Besides, the substrate 500 in the present embodiment is p-type silicon substrate, and the first lightly doped region 505, the second lightly doped region 506 and the third lightly doped region 509 are all n-type doped regions for example. In another embodiment, for example, the substrate 500 is n-type silicon substrate, and the first lightly doped region 505, the second lightly doped region 506 and the third lightly doped region 509 are p-type doped regions otherwise.

It's worthy to note that, to raise the carrier mobility in the thin film transistor 550, a metal layer 540 may be disposed on the gate insulating layer 510 and this metal layer 540 is electrically connected to the double-gate structure 520. FIG. 6C schematically shows a top view of a thin film transistor with a metal layer according to the second embodiment of the present invention, and FIGS. 6D and 6E schematically shows the cross-section diagrams II-II′ and III-III′ in FIG. 6C, respectively. Please refer to FIGS. 6C, 6D and 6E at the same time. A dielectric layer 530 and a metal layer 540 are disposed on the gate insulating layer 510, and wherein the dielectric layer 530 covers the double-gate structure 520 and has an opening 530 located around the position where the first gate 522 and second gate 524 connect. The metal layer 540 is disposed on the dielectric layer 530 and above the double-gate structure 520 and first lightly doped region 505, and it fills in the opening 532 to be electrically connected with the double-gate structure 520.

Particularly, as mentioned above, the metal layer 540 is disposed on the dielectric layer 530 and it covers the first lightly doped region 505 and part of the first channel region 507 and second channel region 508. Therefore, when the thin film transistor 550 is applied on the active-type organic electroluminescent device, the metal layer 540 is able to reflect lights from the organic light-emitting layer (not shown) above the thin film transistor 550 and prevent lights from falling upon the first channel region 507 and second channel region 508 that causes the phenomenon of “photo-leakage current.” Furthermore, the metal layer 540 is formed at the moment that the source metal layer (not shown) and drain metal layer (not shown) of the thin film transistor 550 is formed, so no additional photo-mask fabricating process is required.

To sum up, the thin film transistor based on the present invention owns at least the advantages as follows.

i. By applying the asymmetric lightly doped region structure in the asymmetric double-gate structure, the length of the lightly doped region between the drain and the shorter channel region is larger than that of the lightly doped region between the source region and the longer channel region. Thus, the electric field can be buffered to avoid the effect of short channel.

ii. Formation of the lightly doped region between the two gates of the double-gate structure is provided. This lightly doped region enables the impedance between the source region and drain region to be increased. By doing so, the kink voltage of the thin film transistor can be raised, and accordingly the leakage current can be effectively suppressed. Additionally, because no heavily doped region is formed between the two gates of the thin film transistor, there is no need in dealing with the problem of alignment precision which is required in forming the heavily doped region. Thus, the distance between the two gates could be reduced to minimize the total volume of the devices in the fabricating process of the thin film transistor.

iii. The metal layer disposed on and electrically connected with the double-gate structure is capable of increasing the carrier mobility between the source region and drain region, and reaction rate of devices is raised. Besides, this metal layer along with the source metal layer and the drain metal layer are formed at the same time, so no additional amount of photo-mask of fabricating process is required.

iv. When the thin film transistor of the present invention is applied on the active-type organic electroluminescent display, the metal layer disposed on the lightly doped region is able to reflect lights and avoid the phenomenon of photo-leakage current for the thin film transistor accordingly. Hence, the utility rate of lights for the displays can be lifted and displaying quality can be improved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A thin film transistor, comprising:
a substrate comprising:
a source region and a drain region respectively disposed on opposite sides of the substrate;
a heavily doped region disposed between the source region and the drain region;
a first channel region disposed between the heavily doped region and the source region; and
a second channel region disposed between the heavily doped region and the drain region;
a gate insulating layer covering the substrate;
a double-gate structure comprising:
a first gate disposed on the gate insulating layer above the first channel region; and
a second gate disposed on the gate insulating layer above the second channel region
a first lightly doped region disposed between the second channel region and the heavily doped region; and
a second lightly doped region disposed between the second channel region and the drain region, wherein, the length of the second lightly doped region is larger than the length of the first lightly doped region.

2. The thin film transistor according to claim 1, wherein the width of the second gate is smaller than the width of the first gate.

3. The thin film transistor according to claim 1, wherein the substrate is a p-type silicon substrate.

4. The thin film transistor according to claim 3, wherein the heavily doped region, the first lightly doped region and the second lightly doped region are n-type doped regions.

5. The thin film transistor according to claim 1, wherein the substrate is an n-type silicon substrate.

6. The thin film transistor according to claim 5, wherein the heavily doped region, the first lightly doped region and the second lightly doped region are p-type doped regions.

7. The thin film transistor according to claim 1, wherein a material of the gate insulating layer includes silicon oxide.

8. A thin film transistor, comprising:
a substrate comprising:
a source region and a drain region respectively disposed on opposite sides of the substrate;
a first lightly doped region disposed on the substrate and between the source region and the drain region;
a first channel region disposed between the first lightly doped region and the source region; and
a second channel region disposed between the first lightly doped region and the drain region; and
a second lightly doped region disposed between the second channel region and the drain region;
a gate insulating layer covering the substrate; and
a double-gate structure comprising:
a first gate disposed on the gate insulating layer above the first channel region; and
a second gate disposed on the gate insulating layer above the second channel region.

9. The thin film transistor according to claim 8, further comprising a dielectric layer disposed on the gate insulating layer, wherein, the dielectric layer has an opening and covers the double-gate structure.

10. The thin film transistor according to claim 9, further comprising a metal layer disposed on the dielectric layer and above the double-gate structure and the first lightly doped region, wherein, the metal layer is filled in the opening to be electrically connected with the double-gate structure.

11. The thin film transistor according to claim 8, wherein the substrate is a p-type silicon substrate.

12. The thin film transistor according to claim 11, wherein the first lightly doped region and the second lightly doped region are n-type doped regions.

13. The thin film transistor according to claim 8, wherein the substrate is a n-type silicon substrate.

14. The thin film transistor according to claim 11, wherein the first lightly doped region and the second lightly doped region are p-type doped regions.

15. The thin film transistor according to claim 8, further comprising a third lightly doped region disposed between the first channel region and the source region, wherein, the length of the third lightly doped region is smaller than the length of the first lightly doped region.

16. The thin film transistor according to claim 15, wherein the substrate is a p-type silicon substrate.

17. The thin film transistor according to claim 16, wherein the first lightly doped region, the second lightly doped region and the third lightly doped region are n-type doped regions.

18. The thin film transistor according to claim 15, wherein the substrate is a n-type silicon substrate.

19. The thin film transistor according to claim 18, wherein the first lightly doped region, the second lightly doped region and the third lightly doped region are p-type doped regions.

20. The thin film transistor according to claim 8, wherein a material of the gate insulating layer includes silicon oxide.
